(19) United States
(12) Patent Application Publication
(10) Pub. No.: US 2017/0199022 A1
(43) Pub. Date: Jul. 13, 2017

(54) EXTERNAL COUPLING SENSOR

(71) Applicant: Auckland UniServices Limited, Auckland (NZ)

(72) Inventors: Iain Alexander Anderson, Titirangi (NZ); Daniel Xu, Arkles Bay (NZ)

(21) Appl. No.: 15/321,635

(22) PCT Filed: Jul. 3, 2015
(86) PCT No.: PCT/NZ2015/050082

§ 371 Date: Dec. 22, 2016

(30) Foreign Application Priority Data
Jul. 3, 2014 (NZ) 627048

(51) Int. Cl. G01B 7/16; H03K 17/955; H03K 17/98

(52) U.S. Cl. CPC G01B 7/22; H03K 17/98; H03K 17/955; H03K 2217/96072; H03K 2217/96073; H03K 2217/960765

(57) ABSTRACT

The present invention provides a sensor apparatus comprising a dielectric elastomer device, a power source, a sensor, and a processor. The dielectric elastomer device comprises a layer of dielectric material and a pair of conductive electrodes on opposing sides of the dielectric layer. The power source is coupled with the electrodes to apply a stimulus signal between the electrodes, the stimulus signal comprising two or more stimulus components of different frequencies. A sensor coupled with the electrodes obtains a sensing signal indicative of a frequency response of the dielectric elastomer device. The processor is coupled with the sensor to receive the sensing signal, and configured to detect an external coupling with the dielectric elastomer device based at least in part upon the frequency response of the dielectric elastomer device. Also provided is a method for sensing an external coupling.

### FIELD OF THE INVENTION

This invention relates to an external coupling sensor apparatus and sensing method. More particularly, though not exclusively, the invention relates to a device and method for sensing the position or proximity, contact, and/or pressure upon a dielectric elastomer sensor.

### BACKGROUND

Dielectric elastomer (DE) devices of the prior art are constructed by sandwiching a soft dielectric membrane 10, typically of silicone or an acrylic elastomer material, between two compliant electrodes 11a, 11b as shown in FIG. 1. The devices may be used as actuators, generators, or sensors.

For example, geometric changes to a dielectric elastomer sensor under tension (in the planar direction) or compression (in a through-plane direction) deform the membrane and electrodes of the device, causing changes to the overall capacitance and resistance of the sensor which can be used to infer useful sensing information such as strain or force. Such dielectric elastomer sensor devices have therefore previously been used as stretch sensors.

Examples of dielectric elastomer sensing devices and methods of the prior art are disclosed by International Patent Publication Nos. WO 2010/095960 and WO 2012/053906.

A limitation of such dielectric elastomer sensing devices and methods is that they assume or require that the dielectric elastomer device is deformed substantially uniformly. The devices and methods of the prior art are incapable of providing any positional information. That is, they are not capable of determining the precise location of a force or determining a point of contact of an external object deforming the device.

A second limitation is that while it is relatively straightforward to measure the capacitance of one DE, each sensor must be married to a pair of cables and interrogation electronics. This adds complexity to the peripheral circuitry, increasing the chance of sensor interference and cross-talk. Multiple channels can also reduce the software processing speed as the capacitance sensing algorithms that can accommodate the DE's high electrode resistance are generally computationally intensive. Proposed solutions such as arrays of analogue multiplexors, decoders, hardware processing and capacitance to digital pulse train converters do not make the approach suitably straightforward.

### OBJECT OF THE INVENTION

It is an object of the invention to provide a dielectric elastomer device and/or a method which overcomes or at least ameliorates one or more disadvantages of the prior art, or alternatively to at least provide the public with a useful choice.

It is a further object of the invention to provide a dielectric elastomer device and/or a method which allows a single DE sensor to act as multiple sensors and/or to sense the position of an external coupling.

Further objects of the invention will become apparent from the following description.

### SUMMARY OF INVENTION

In a first aspect the invention may broadly be said to consist in a sensor apparatus comprising:
a dielectric elastomer device comprising a layer of dielectric material and a pair of conductive electrodes on opposing sides of the dielectric layer;
a power source coupled with the electrodes to apply a stimulus signal between the electrodes, the stimulus signal comprising two or more stimulus components of different frequencies;
a sensor coupled with the electrodes to obtain a sensing signal indicative of a frequency response of the dielectric elastomer device; and
a processor coupled with the sensor to receive the sensing signal, and configured to detect an external coupling with the dielectric elastomer device based at least in part upon the frequency response of the dielectric elastomer device.

The external coupling may comprise a mechanical and/or electrical coupling. More specifically, the external coupling may comprise a mechanical coupling causing deformation of the dielectric elastomer device which affects the internal capacitance thereof, or a coupling of an external capacitance by way of contact or proximity of a human finger, for example.

Preferably the processor is configured to detect at least one of, and more preferably two or more of, a condition, degree, and position of said coupling.

Preferably at least one of the two or more stimulus components is at least partially attenuated by the dielectric elastomer device. The attenuated stimulus component is attenuated by the combined effect of a distributed resistance of the electrodes and a distributed capacitance between the electrodes, which together act as a low-pass filter. More preferably at least one of the two or more stimulus components is not attenuated by the electrodes. Selection of appropriate frequencies will depend upon the design of the dielectric layer and electrodes, or vice versa.

Preferably the processor is configured to process the sensing signal to identify two or more sensing components of the sensing signal, each attributable to one of the two or more different stimulus components of the stimulus signal.

Preferably the processor is configured to perform a Fourier transform on the sensing signal to identify the two or more sensing components corresponding to the two or more stimulus components.

Alternatively, the processor may comprise one or more filters configured to identify the two or more sensing components.

Preferably the processor is configured to calculate, for each of the two or more sensing components, a capacitance of the dielectric elastomer device based at least in part on the respective sensing component. The capacitance calculated from a sensing component corresponding with the at least one attenuated stimulus component is indicative of the capacitance between a portion of the electrodes of the dielectric elastomer device, whereas the capacitance calculated from a sensing component corresponding with an un-attenuated stimulus component is indicative of the overall capacitance between the electrodes of the dielectric elastomer device. The portion of the electrodes is proximate terminals of the electrodes to which the power source and sensor are coupled.

Preferably the stimulus signal comprises a periodic impulse.

Alternatively, the stimulus signal may comprise a non-sinusoidal waveform comprising two or more different frequency components, such as a square, triangle, or saw-tooth wave for example.

Alternatively, the stimulus signal may cycle between the two or more different frequency components.

Alternatively, the stimulus signal may sweep through a predetermined frequency range.

Preferably the processor is further configured to compare the calculated capacitances with corresponding reference capacitances for each of the different sensing components, wherein a variation between the calculated capacitance and the reference capacitance is indicative of the external coupling.

Preferably each reference capacitance corresponds to a capacitance calculated from the respective sensing component when the dielectric elastomer device has no external coupling.

Preferably each of the calculated capacitances corresponds with a portion of the dielectric elastomer device, each of the portions extending distally over an area having an inverse relationship to a frequency of the respective stimulus and/or sensing component. Thus a capacitance calculated on the basis of a lower frequency sensing component may correspond to a larger portion of the dielectric elastomer device (potentially the entire dielectric elastomer device), whereas a capacitance calculated on the basis of a higher frequency sensing component may correspond to a smaller portion of the dielectric elastomer device. The respective portions may overlap.

Preferably the processor is configured to detect the position of the external coupling based at least in part upon which of the calculated capacitances vary from their respective reference capacitances.

Preferably an absence of variation in the calculated capacitance corresponding to the lowest frequency is indicative of no external coupling of the dielectric elastomer device; a variation in the calculated capacitance corresponding to the lowest frequency is indicative of the external coupling with the dielectric elastomer device; and a number of calculated capacitances corresponding with each of the different frequencies which vary from the respective reference capacitance is indicative of a position of the external coupling.

Preferably the processor is configured to sequentially compare the respective calculated capacitances and reference capacitances in ascending order of a frequency of the corresponding stimulus/sensing components, wherein:
an output signal indicating no external coupling of the dielectric elastomer device is provided if the first calculated capacitance does not vary;
an output signal indicating of the external coupling with the dielectric elastomer device is provided if the first calculated capacitance varies; and/or
an output signal indicating a position of the external coupling with the dielectric elastomer device is provided if at least one of the calculated capacitances varies, wherein the position is determined by identifying a first occurrence of a calculated capacitance in the sequence which does not vary.

Preferably the stimulus signal comprises a plurality of stimulus components of sequentially increasing frequency. More particularly, the frequency difference between each sequential stimulus component is equal.

Preferably the comparison between calculated and reference capacitances comprises a minimum margin of difference for indicating a variation. The comparison may comprise a hysteresis or Schmitt trigger.

Preferably the controller is configured to provide an output signal indicative of the position of the external coupling.

Preferably the controller is configured to detect the degree of the external coupling based at least in part upon the degree of variance from the respective reference capacitance.

Preferably the processor is further configured to provide an output signal indicative of the degree of the external coupling.

Preferably the sensor apparatus comprises a one-dimensional sensor, wherein the dielectric elastomer device has a substantially elongate planar shape.

Alternatively, the sensor apparatus may comprise a two-dimensional sensor, wherein the dielectric elastomer device is substantially planar.

Alternatively, the sensor may comprise a three-dimensional sensor wherein the dielectric elastomer device is non-planar, for example. The dielectric layer and electrodes may be arranged in a cylindrical shape, for example.

Preferably the dielectric layer comprises an elastomer membrane and the electrodes are compliant whereby at least part of the sensor is pliable.

Preferably the dielectric layer has a substantially uniform thickness across its area. Alternatively, the thickness of the membrane may vary across its area, and in particular may vary progressively in at least one direction.

Preferably the electrodes each have a substantially uniform resistivity across their area. Alternatively, either or both of the electrodes may have a non-uniform resistivity, and in particular map comprise a varying concentration of a conductive electrode material or a plurality of conductive electrode materials across their area.

Preferably the electrodes each comprise a substantially planar sheet. Alternatively, either or both of the electrodes may be patterned, and in particular may be patterned into one or more spiral patterns.

The device may further comprise a conductive mesh coupled to an electrode to reduce its effective resistance.

Preferably the processor comprises a microcontroller and/or digital signal processor.

Preferably the sensor comprises at least one electrical sensor, the at least one electrical sensor configured to sense one or more of a potential difference across the dielectric elastomer device, a current through the dielectric elastomer device, and a charge supplied to the dielectric elastomer device.

In a second aspect the invention may broadly be said to consist in a sensor apparatus comprising:
a layer of dielectric material;
a pair of resistive electrodes on opposing sides of the dielectric layer;
a power source coupled with the electrodes to apply a stimulus signal to the electrodes at two or more different frequencies, wherein at least one of the frequencies is at least partially attenuated;
a sensor coupled with the electrodes to sense an electrical parameter of the electrodes in response to the applied stimulus signal; and
a processor coupled with the sensor to receive a sensing signal therefrom, and configured to estimate, for each of the two or more different frequencies, a corresponding capacitance between the electrodes, and to detect a position of an external coupling with the dielectric material and/or at least one of the elect odes based at least in part upon the estimated capacitances.

Preferred features of this second aspect of the invention will be apparent from the corresponding preferred features of the first aspect.

In a third aspect, the invention may broadly be said to consist in a method for determining a position of an external coupling with an electrode of a dielectric elastomer device, the method comprising steps of:
applying a stimulus voltage to the electrode, the stimulus voltage comprising a plurality of components of different frequencies;
measuring a current and/or voltage of the electrode attributable to each of the different frequencies;
detecting variations in the current and/or voltage measurements for each of the different frequencies, with respect to corresponding reference values; and
determining a position of the external coupling based at least in part on the frequencies for which said variations are detected.

Preferably at least one of the different frequencies is attenuated by the dielectric elastomer device. More preferably, one of the plurality of frequencies is not attenuated by the dielectric elastomer device, and a plurality of other frequencies are attenuated by the dielectric elastomer device to different degrees.

Preferably the method comprises performing a Fourier transform on the current and/or voltage measurements.

Preferably the method further comprises calculating a capacitance based on the current and/or voltage measurements for each of the different frequencies, and detecting variations in the calculated capacitances with respect to corresponding reference capacitance.

Preferably the method is performed by sensing electronics. More particularly, the steps of detecting changes in the current and/or voltage and determining the position of the external coupling are preferably performed by a processor, and most preferably a microcontroller.

Preferably the method comprises sequentially comparing the respective measurements and reference values in ascending order of the respective frequency, wherein the position is determined by identifying a first occurrence of a calculated capacitance in the sequence which does not vary from the reference value.

In a further aspect the invention may broadly be said to consist in a method for determining a position of an external coupling with a dielectric elastomer device, the method comprising steps of:
applying a stimulus signal to the dielectric elastomer device; the stimulus comprising a plurality of stimulus components of different characteristics;
measuring a response of the dielectric elastomer device to each of the plurality of stimulus components;
determining an external coupling based at least in part on the variation in the response of the dielectric elastomer device to the plurality of stimulus components.

This aspect of the invention is adapted to detect when there is contact, or spatial closeness or proximity to a DED and it is desirable to locate a position on the DED near the contact. The stimulus signal to the dielectric elastomer is sufficient to measure a response from the DED to each of the plurality of stimulus components. The stimulus signal may be an electrical signal of varying voltage, current and/or frequency at least. The different stimulus components allow the responses at each of the stimulus components to be compared. The characteristic of the stimulus components is chosen so that it varies dependent on the position of an external coupling. For instance, an external coupling will affect signals of different frequencies by different amounts. A comparison, for instance a comparison to predetermined response curves, of the different responses of the dielectric elastomer device to the different components allows the position of the external coupling to be determined.

Preferably the stimulus signal is an electrical signal having a varying current and/or voltage.

Preferably the stimulus supplies the two or more stimulus components concurrently.

Preferably the stimulus supplied the two or more stimulus components consecutively or separated in time.

Preferably the characteristic is frequency.

Preferably the method comprises the step of separating the response in to responses for each of the stimulus components.

Preferably the stimulus components are frequencies and these are separated using a frequency transform, such as a Fourier transform.

In a preferred example the stimulus signal is an electrical signal having a plurality of frequency components, the frequency components being combined concurrently to form a single signal. The frequency of the signal affects the propagation of the signal in to the DED and therefore a comparison between different frequencies can determine where the external coupling has occurred. Alternatively, or in conjunction, the frequency components may be applied to the DED in turn or consecutively. Where the stimulus is combined concurrently this is preferably in a multi-frequency signal. The response at each frequency can then be separated by performing a Fourier transform such as a FFT. Other methods of converting to the stimulus domain, e.g. frequency domain may also be used.

Preferably the method is associated with a dielectric elastomer device comprises a layer of dielectric material and a pair of conductive electrodes on opposing sides of the dielectric layer;

Preferably the method comprises the step of determining the number of external couplings based at least in part on the variation in the response of the dielectric elastomer device to the plurality of stimulus components.

Preferably the method comprises the step of determining a plurality of positions of external couplings based at least in part on the variation in the response of the dielectric elastomer device to the plurality of stimulus components.

Preferably the method comprises the step of comparing the response for at least one of, or each of, stimulus components to a reference measurement or a reference curve or curves.

Preferably the reference measurement or curve or curves are predetermined.

Preferably the step of determining a position comprises determining the difference in response measured by a first stimulus component relative to a second stimulus component.

Preferably the step of determining a position comprises determining the difference in response measured by a first stimulus component and a second stimulus component relative to a reference stimulus component.

The stimulus components can each be measured relative to their absolute position along the DE, or the measurement can be only the difference between two stimulus components to reduce the noise in the signal.

Preferably the threshold or minimum margin of difference is applied to the measurement to determine a position of the external coupling.

Preferably the dielectric elastomer device is elongate, so that its length is longer than its width. In an embodiment the dielectric elastomer device may be of variable width or length.

Alternatively the dielectric elastomer is a sheet. Preferably the sheet is substantially planar.

Preferably the stimulus signal is applied at a first position and a plurality of responses are measured at response positions. Preferably the response positions may be spread over an area or volume of a 2d or 3d sensor respectively.

Preferably the stimulus signal is applied to a first and second sheet arranged on axis angled in respect of each other. Preferably the axes are orthogonal. Preferably the angles is 90 degrees.

Preferably the first position is substantially a first corner of the sheet. Preferably the response positions are substantially opposite corners of the sheet. Preferably the response positions are substantially symmetrical about a line of symmetry of the sheet.

Preferably the method comprises the step of placing the dielectric elastomer device in a structure adapted to localise or amplify the effect of external coupling with the dielectric elastomer device.

In a further aspect the invention may broadly be said to consist in a sensor apparatus comprising:
a dielectric elastomer device;
a source coupled with the dielectric elastomer device to apply a stimulus signal to the dielectric elastomer device, the stimulus signal comprising a plurality of stimulus components of different characteristics;
a sensor coupled with the dielectric elastomer device to obtain a sensing signal indicative of a response of the dielectric elastomer device; and
a processor coupled with the sensor to receive the sensing signal, and configured to detect an external coupling with the dielectric elastomer device based on the variation in the response of the dielectric elastomer device to the plurality of stimulus components.

This aspect of the invention is adapted to provide a DED sensor adapted to detect when there is contact, or spatial closeness or proximity to a DED and it is desirable to locate a position on the DED near the contact. The stimulus signal to the dielectric elastomer is sufficient to measure a response from the DED to each of the plurality of stimulus components. The stimulus signal may be an electrical signal of varying voltage, current and/or frequency at least. The different stimulus components allow the responses at each of the stimulus components to be compared. The characteristic of the stimulus components is chosen so that it varies dependent on the position of an external coupling. For instance, an external coupling will affect signals of different frequencies by different amounts. A comparison, for instance a comparison to predetermined response curves, of the different responses of the dielectric elastomer device to the different components allows the position of the external coupling to be determined.

Preferably the stimulus signal supplies the two or more stimulus components concurrently or simultaneously.

Preferably the stimulus signal supplied the two or more stimulus components consecutively or separated in time.

Preferably the dielectric elastomer device comprises a layer of dielectric material and a pair of conductive electrodes on opposing sides of the dielectric layer.

Preferably the characteristic is frequency.

In a further embodiment the invention may be said to consist in a 2D dielectric elastomer sensor adapted to detect position in a first and second direction. Preferably the dielectric elastomer is malleable or flexible to conform to a surface or shape.

In a further aspect the invention may be said to consist in a method for determining a position of an external coupling to a dielectric sensor, the method comprising the steps of:
Applying a stimulus signal to the dielectric sensor, the stimulus signal comprising a plurality of signals with a different characteristic;
Detecting a response signal from the dielectric sensor;
Determining a position of the external coupling based at least in part on the different characteristic for which said responses are detected.

Preferably the characteristic is frequency.

Preferably the plurality of signals can be combined concurrently or consecutively in time.

In a further aspect the invention may be said to consist in a dielectric sensor using or adapted to be used for any one or more of the methods described herein.

Further aspects of the invention, which should be considered in all its novel aspects, will become apparent from the following description.

### DRAWING DESCRIPTION

A number of embodiments of the invention will now be described by way of example with reference to the drawings in which:

FIG. 1 is a diagram of a dielectric elastomer device according to the prior art;

FIG. 2 is an electrical model of the dielectric elastomer device of FIG. 1 as used by the methods of the prior art;

FIG. 3 is an electrical model of a dielectric elastomer device according to the present invention;

FIG. 4 is a simplified electrical model of a dielectric elastomer device according to the present invention;

FIG. 5 is a diagrammatic illustration of a dielectric elastomer device and attenuation of stimulus signals according to the present invention;

FIG. 6 is a graph showing the calculated capacitance of a dielectric elastomer device based on a range of stimulus signals as exploited by the present invention;

FIG. 7 is a diagram of a simplified electrical model of a dielectric elastomer device, illustrating attenuation of stimulus signals according to the present invention;

FIG. 8 is a flowchart illustrating an example algorithm for determining a location of applied pressure on a dielectric elastomer device according to the present invention;

FIG. 9 is a block diagram of a sensor apparatus according to the present invention.

FIG. 10 is a diagram of a sensor apparatus interpreted with a transmission line model having a continuum of resistive and capacitive elements according to the present invention.

FIG. 11 is a series of plots showing (a) at low sensing frequencies, the voltage is constant along the length of the DE (b) but becomes attenuated as the frequency is increased. This effect can be reduced (c) by reducing the resistance of the electrodes, and (d) a dielectric elastomer sensor according to the present invention.

FIG. 12 is a block diagram of single reference using the absolute capacitance measured at each frequency to determine position, and differential reference using the differences between two capacitance measurements to determine deformation according to the present invention.

FIG. 13 is a diagram showing how the lumped capacitance of the DE can be calculated by measuring the amplitude and phase shift of current under a sinusoidal voltage excitation according to the present invention.

FIG. 14 is a diagram of a sensor apparatus single DE sensor split into four sensing regions to represent different positions according to the present invention.

FIG. 15 is a block diagram of a sensor apparatus sequentially sweeping through each sensing frequency and measuring all the frequencies at the same time using a frequency transform according to the present invention.

FIG. 16 is a flow chart of the operation of a sensor apparatus according to the present invention wherein to play the correct note, first the sensing signals are combined together and sent to the DE sensor. Then a FFT is used to determine the amplitude and phase of each frequency component to calculate its capacitance. Finally a matching algorithm is used to identify which key was pressed to play the corresponding sound via the loudspeaker.

FIG. 17 is a diagram of a sensor apparatus fixed in a plastic frame to isolate strain to the local regions according to the present invention.

FIG. 18 shows charts of capacitance frequency response of single and multi-touch positions providing unique characteristic profile according to the present invention.

FIG. 19 is a chart of how pressing locations further down the transmission line shows a lower change in capacitance according to the present invention.

FIG. 20 is an example of a 2 dimensional sensing where 2 electrodes measure the return current at opposite ends of a sensor apparatus according to the present invention.

FIG. 21 is a diagram of comparing the relative capacitance of the 2D dielectric elastomer sheet at opposite corners to determine the X and Y location of the position of deformation a sensor apparatus according to the present invention.

FIG. 22 shows how additional ground electrode layers can be added to shield the sensor from environmental noise according to the present invention.

FIG. 23 shows an embodiment of a 2 Dimensional sensor where multiple 1-D sensors are combined.

### DETAILED DESCRIPTION OF THE DRAWINGS

If dielectric elastomer sensors are able to sense the position of a pressure contact they may provide a soft alternative to traditional hard tops and button keys. These sensors may be used to create a soft-touch musical keyboard which can help reduce the impact loading while playing the keyboard or using the sensor. Possible additional benefits of a soft keyboard include featherweight construction and a high degree of robustness. DE sensors can also be configured in various shapes and sizes, giving a user a higher level of customizability. For example this could allow the keyboard player to easily configure the keys to suit their playing style. However these systems require information regarding local deformation within the DE, which has not previously been measurable. In an embodiment of the invention a new multi-frequency capacitive sensing method is used to divide the sensor into a plurality of different regions.

Although this specification broadly discusses the detection of a capacitance in the sensor it should be understood that other characteristics of the dielectric sensor or the response to the stimulus signal may be measured or detected. In particular the detected characteristic may be a relationship between a voltage and current supplied to or received from the sensor. For instance other terms may be used that a machine learning algorithm can pick up. Preferably a tangible relationship is used. Capacitance may be preferred because it can be directly relatable to geometry of the sensor and other terms can be less tangible. In general embodiment a raw or original signal is measured (e.g. voltages and currents) and converted or calculated to an electrical parameters (e.g. capacitance, resistance, impedance) using a model to infer position. A preferred embodiment uses the lumped value of capacitance at different frequencies to infer pressure on the dielectric elastomer 1. The raw current and voltage levels can be difficult to relate to the sensor or material properties whereas capacitance is governed geometrically and environmentally stable. Capacitance is typically calculated from a change in measured voltage and current levels (both magnitude and phase).

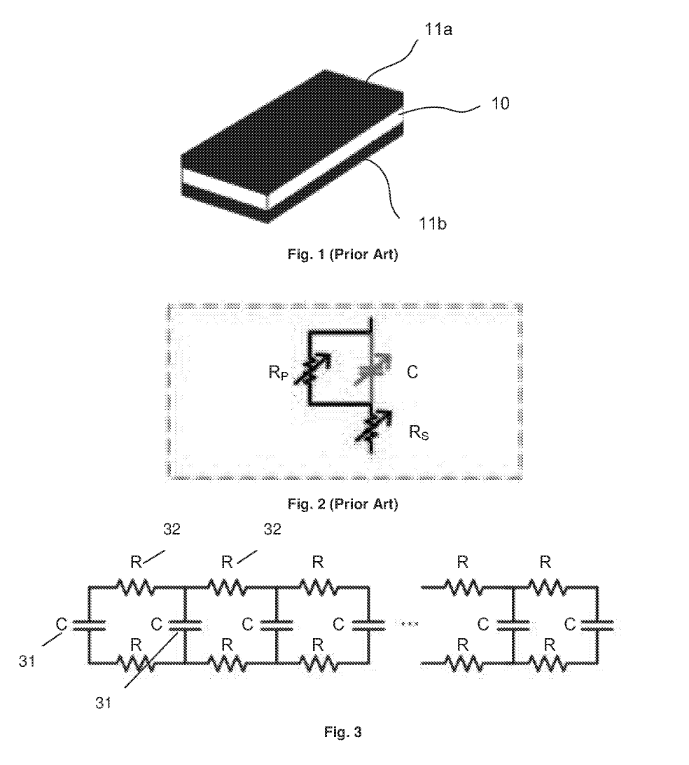

The loss of positional information in the dielectric elastomer devices and methods of the prior art is in part a consequence of the lumped parameter model used to represent the dielectric elastomer sensor, as shown in FIG. 2. The lumped parameter model groups together all resistive and capacitive elements of the system and defines them as a series resistance R_{S} (electrode resistance) in series with a parallel resistance R_{P} (membrane resistance) and capacitance C. This capacitance, C, allows a determination of a DE's overall area (A) and thickness (t) from knowledge of, ∈, the relative permittivity,

Although the equivalent capacitance of the dielectric elastomer sensor has been shown to be a good predictor of the overall strain of the sensor, it fails to identify localized deformations or the position thereof because it treats the sensor as a single capacitive and resistive element.

An example of a situation in which positional information such as localised deformations or a point of contact is useful includes using the dielectric elastomer sensor as a human interface device by detecting contact and movement of a human finger upon an electrode of the sensor.

Typically, the electrodes of low-cost dielectric elastomer sensors are made from highly resistive carbon-based materials. This relatively high resistance of the electrodes was viewed as a problem, or at least non-ideal, as it made determining the capacitance of the sensor difficult. However, this high resistance is exploited by the present invention to provide positional or localised proximity, touch, and/or pressure information. Furthermore little, if any, consideration has previously been given to analysis of dielectric elastomer devices in the frequency domain rather than the time domain, and development and implementation of dielectric elastomer devices has therefore been limited to a DC mind-set or low-frequency (e.g. 1 Hz) operation.

In an embodiment the system may be broadly described as a localisation method that relies on a negative voltage gradient and the use of different sensing frequencies to alter the point at which capacitances in a DE sensor become unapparent to the measurement device. In a first embodiment the DE is represented as the proportion of capacitors that constitute the lumped capacitance value measured from the origin. Because the parameter (e.g. capacitance) is frequency dependent, i.e. the reach of the sensing signal can be adjusted by altering its frequency. In alternative embodiments the parameter (or response of the sensor to the parameter) may be dependent on some other stimulus component(s) characteristic (i.e. the response changes depending on that characteristic). For instance the response may change dependent on the level of voltage or current applied to the dielectric sensor; alternatively the time or delay of response, or phase or other characteristic. By sourcing a signal to the sensor, sensing the response of the dielectric sensor and detecting differences in the responses of the characteristics to the dielectric sensor a position of an external coupling can be detected. While frequency is described herein as a stimulus component characteristic it should be considered that alternative characteristics may also be used.

In embodiments of the invention parameters including reactance or impedance or inductance may be used instead of capacitance or in combination. In an embodiment the measured parameter may be any electrical variable that changes in value with position along the dielectric sensor. Capacitance may be a preferable choice because it can be correlated to the sensor's geometry in a straightforward manner. This enables a greater portion of the DE to be progressively measured by reducing the sensing frequency and then use the difference between two frequencies to infer the capacitance between these sections.

A distributed model can be used when there is a large electrode resistance as this enables an assumption to be made that the capacitance cannot be lumped into a single element. DEs can also behave in this way when its electrode resistance is high. At a granular level, this can be modelled by chains of resistor and capacitor sections connected in a ladder network. This model effectively segregates the sensor into many smaller sensors. By measuring capacitive changes in differential sections of the DE, we can determine where the press occurred. In embodiments of the invention there may not be physical contact or the amount of physical contact (pressure) may vary. Therefore the lumped parameter model of the prior art may be broken down to a distributed transmission line model of distributed resistances and capacitances, represented in the diagram by discrete capacitive C 31 and resistive elements R 32 as shown in FIG. 3. When the sensing voltage is low, the membrane resistance R_{P} can be neglected.

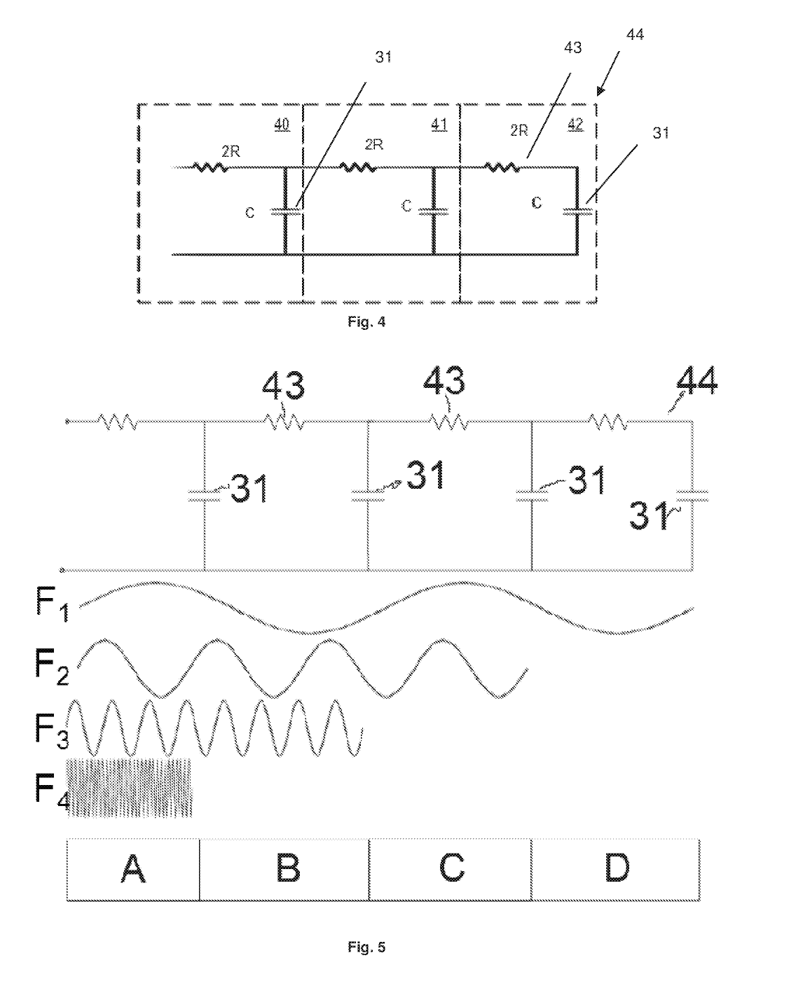

This transmission line model represents a continuous distribution of resistance and capacitance within the dielectric elastomer. In an ideal case, the distribution is homogenous throughout with the parameters R and C representing resistance and capacitance per length, respectively. The transmission line model of FIG. 3 can be further simplified to a series of RC stages 40, 41, 42 where the parallel resistances, R 32, are each combined into a single value of 2R 43 as shown in FIG. 4.

Electrically, each stage 40, 41, 42 represents a low-pass filter, where frequencies below the cut-off frequency are easily passed through but higher frequencies are attenuated to at least some degree. The cut-off frequency for a low pass filter is described by Equation 1. Each stage of the low pass filter further attenuates high frequency signals.

$${f}_{c} = \frac{1}{2 π ( 2 R ) C} \qquad ( 1 )$$

The result of this series of low pass filters is that high frequency signals cannot propagate far into the sensor, while low frequencies can still comfortably propagate to the end of the sensor. The higher the stimulus frequency, the more it becomes attenuated and thus propagates even less into the sensor. Because a stimulus signal cannot measure beyond its reach, this creates an opportunity to selectively ‘sense’ different areas of the sensor by using different stimulus signals that propagate a different amount into the sensor. That is the voltage, or other signal, will become so small in amplitude that it will fail to transfer enough charge onto the capacitors 31 remaining in the line to sufficiently detect their capacitance. At this stage, the appearance of these remaining capacitors to the DE will be minimal, thereby resulting in a smaller apparent lumped capacitance value.

The transmission line 44 of FIG. 3 can also be considered by applying a transmission line model to analyse the internal effects of the DE. In particular, the voltage attenuation along a 1-dimensional strip can be described by solving the pair of Telegrapher's Equations:

∂V∂z=−L′∂l∂t−R′I

∂I∂z=−C′∂V∂t−G′V

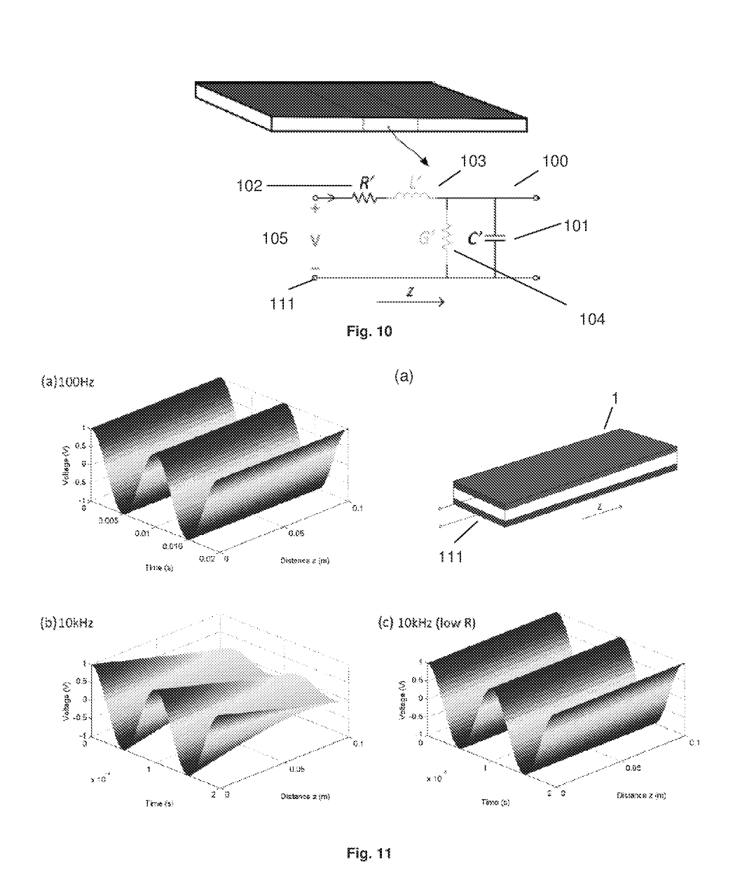

Adapting the lossy transmission line model we can represent the DE 1 as a distributed series in a lossy transmission line 100 model where R′ 102 and C′ 101 represents the resistance and capacitance per unit length respectively as shown in FIG. 10. By using a relatively short length and a low sensing voltage 105, we can ignore the inductance 103 (L′) and conductance 104 (G′) terms in the model. In one method the solution to the pair of differential equations can be solved analytically using the Laplace transform. The general form of the voltage solution can be expressed as

V(z,t)=V+ê(jωt−ζz)+V−ê(jωt+ζz)

where ω is the angular frequency of the input voltage, ζ is the wave propagation constant:

ζ=√(R′+jωL)(G′+jωC′)

and V+ and V− represent the magnitudes of the voltage wave travelling forward and backward along the transmission line.

The transmission line model is able to distinguish localised pressure changes inside the DE, therefore eliminating the need for multiple discrete sensors. A tuneable parameter (frequency) was identified as a control variable to alter the interrogation length of the sensing signal. However the mathematics typically assumes the system to be homogenous in nature with a constant capacitance and resistance throughout. In situations where this assumption is not accurate sharp discontinuities can appear in the attenuation of the sensing signal. In an embodiment of the invention a change in the physical parameters of the invention may be embedded in the model so as to anticipate these discontinuities. Alternatively a DE 1 with consistent parameters along its length will reduce or avoid this issue. Similar to a less than ideal filter with a vertical drop-off, the decay of the sensing voltage 105 is gradual and non-linear. This was shown by a small amount of cross-over between the measured capacitance at different frequencies when neighbouring keys were pressed. One solution to counter this was to apply a threshold that the capacitance has to change by to definitively register as a press. A 10 pF threshold was used in the DE keyboard experiments but this will depend on the relative capacitance of the DE.

FIG. 11 shows an example where a DE 1 is simulated as 0.1 m long with properties of =1 MOhm/m 102 and C′=1 nF/m 101. At a sending frequency of 100 Hz, FIG. 11a, the sensing voltage is uniform through the entire length of the DE. In effect the sensor sees the same sensing signal in time. However at 10 kHz the capacitance is having more effect and the voltage decreases significantly in amplitude the further away from the connection point (FIG. 11b). This voltage decrease effect can be countered by reducing the resistance of the electrodes (FIG. 11c).

Therefore there may be a trade-off between the length of the sensor and the sensitivity, as a high R provides sensitivity but voltage decays more quickly. Similarly in situations where high frequency can be used a lower resistance may be used. When alternative parameters are used the trade-off may be between the parameter and an alternative characteristic or material property of the DE 1, or may also be resistance. This simulation shows that the resistance parameter R′ 102 has a strong influence in the attenuation of the sensing voltage. However the frequency of the sensing signal can serve as a counter balance against high resistance, acting as a way to adjust the level of penetration. It is also evident that eventually, the sensing voltage will become insignificant in size rendering it ineffective at measuring the remaining capacitors in the line. In an embodiment this voltage attenuation is exploited by using different sensing frequencies to alter the reach of the sensing signal. The negative voltage which is apparent along the length of the electrodes means that the amplitude of the sensing voltage will become smaller the further away from the connection point. At some point the voltage becomes so small in amplitude that it fails to push enough charge onto the capacitors remaining in the line to sufficiently detect their capacitance. In this state, the contribution of these capacitances is minimal and therefore underrepresented in the lumped capacitor model, resulting in a smaller total capacitance measurement

The resistance of the electrodes was previously viewed as an unfavourable characteristic of ‘bad electrodes’. However in this approach the high resistance transmission line creates a voltage gradient that creates the reduction in measured capacitance with frequency. By using sufficiently ‘bad’ electrodes, we can shift the frequency bandwidth to lower frequencies to avoid inductive (and RF) effects which become increasingly large at high frequencies, as well as relaxing sampling requirements. That is a more resistive dielectric will shower greater change in capacitance when a position is pressed or proximity detected.

For example, a sensor 50 can be divided into a plurality of segments A-D where a plurality different stimulus frequencies f₁-f₄ can be used to measure different segments. A system of 4 positions is shown diagrammatically in FIG. 5. It should be understood that the device is not limited to 4 or 5 positions as described in this document but may have more or less positions. Different key sizes or positions may be achieved by adjusting the sensing signal (e.g. frequency) to be sensitive to be receptive or sensitive at any point of the continuous sensor. The realisation of the sensitivity may be limited by the non-homogeneity of the sensor or ability to separate nearby positions. However in some embodiments substantially continuous measurement may be obtained (or the keys may be of such size that measurement may appear continuous). Therefore in some embodiments it is advantageous to discretize or divide the sensor into a plurality of regions. This division may be physical or simply in the processed response or a mixture of these. In this example, the sensor apparatus comprises a one-dimensional dielectric elastomer device as an elongate strip sensor. A power source 105 supplying the stimulus signal and sensor making measurements of an electrical parameter of the dielectric elastomer device are preferably coupled with terminals 111 at one end of the elongate electrodes.

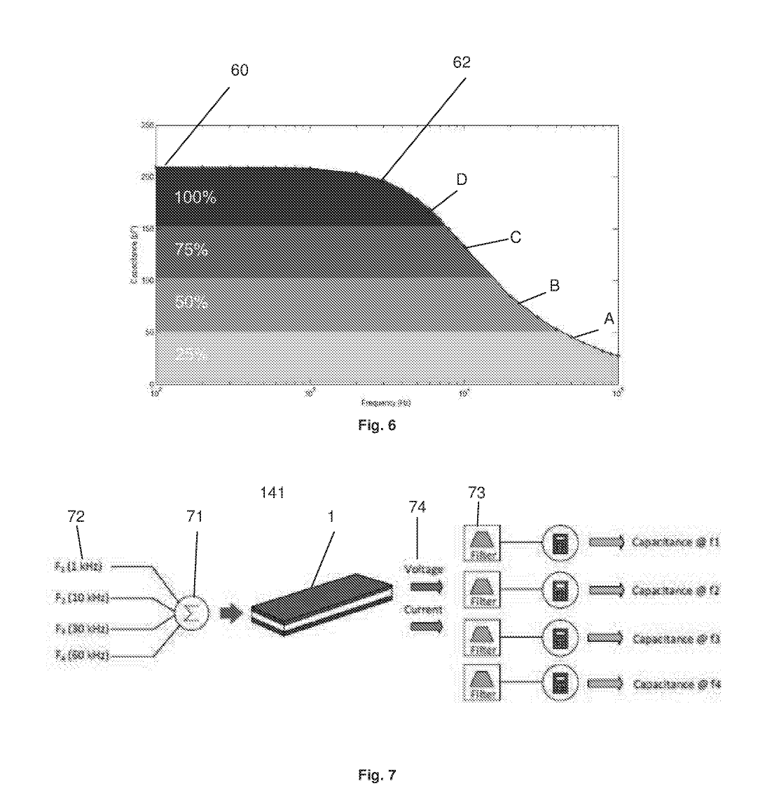

FIG. 6 illustrates the capacitance of a static dielectric elastomer device of nominally 250 pF as calculated from measurements using a range of stimulus frequencies. It can be seen that as the stimulus frequency increases, the amount of capacitance 60 it measures decreases. An initial model of the electrode resistance and capacitance distribution can be used to determine an appropriate selection of stimulus frequencies. The lowest frequency component f₁ should be capable of measuring the full capacitance of the entire sensor. This capacitance of a dielectric elastomer can be determined using a reference signal to obtain the characteristics of a lumped capacitance model. The DE 1 is excited with a sinusoidal signal and the relationship between the voltage and current may be used to determine electrical parameters. FIG. 13 shows the relationship between the voltage and current which is summarised in the equation:

I(jω)/V(jω)=1/(R+1/jωC)

Equating the complex magnitude and phase angle of this expression leads to an equation for the lumped capacitance of the DE:

C=B/(Aω sin φ)

To identify the sensing signal to measure each region, a frequency sweep (100 Hz to 100 kHz) of the DE's series capacitance can be conducted using an adjustable LCR meter. FIG. 6 shows a steady measurement at low frequencies, signifying the nominal capacitance of the DE 1 followed by a sharp decrease beyond a corner or cut-off frequency 61. Because these tests were conducted at low voltage with no physical changes in the DE's geometry, it is important to note that the measured capacitance drop was an artefact of the lumped parameter assumption and not because of an actual change in the DE's total capacitance. That is the capacitance is defined, at least in part, by the geometric and material properties of the sensor. The measured change in capacitance with the frequency change is not an actual change in capacitance of the DE but is created by the lumped capacitance assumption that capacitance is constant with frequency. In this embodiment the variation of apparent capacitance at different frequencies is used to infer local changes in capacitances caused by, for instance, a contact with the sensor.

In an embodiment the capacitance measured at each frequency is represented as an equivalent lumped capacitor. This may be thought of as representing a proportion of the number of capacitors in the transmission line (where the sensor/transmission line is thought of as a string of parallel capacitors, FIG. 4). In one embodiment the detection may be by means of creating a characterisation of the response of the sensor to a, or the, range of characteristics of the sensing signal (e.g. the capacitance at a variety of frequencies). This may be interpreted as a number of capacitors in the transmission line being measured at each frequency. A processor may be used to determine a relationship between source and receiver voltage and currents. For instance an algorithm that calculates lumped value capacitance from a voltage and current signal. A possible method uses a Hyper-plane. In other embodiments methods include a gain/phase shift from a sinusoidal signal or integration of current to determine amount of charge transferred to the capacitor.

Multiple stimulus signal components can be combined 71 together into a stimulus signal such as an electrical chirp or impulse, which may be represented by a summation of components of different frequencies f₁-f₄ as shown in FIG. 7, to be simultaneously applied to the input or electrodes of the dielectric elastomer device 1. Alternatively, an oscillatory or non-oscillatory waveform of multiple frequency components such as a square wave, triangle wave, or saw-tooth wave can be used as the stimulus signal.

The stimulus signal 152 has a plurality of stimulus components 72 (these may be separated in time or frequency) which respond differently, or differentiate themselves, when sourced to the dielectric elastomer sensor. The stimulus components 72 have different characteristics (e.g. frequencies) that cause, or effect, the response of the sensor to the stimulus signal. By having a plurality of stimulus components with different characteristics the response can be measured for each of those characteristics and a variation or comparison of the response changes can enable the detection of an external coupling and the position of the external coupling.

The resulting output or sensing signal 74, sensed by a voltage or current sensor coupled with the electrodes of the dielectric elastomer device, can be separated into different stimulus components 72 or frequency components by a fast Fourier transform (FFT) or filter/s 73, transforming the measurements from the time domain to the frequency domain. The separated sensing signals may then be processed by a processor 73 into a preferred reading format, e.g. capacitance.

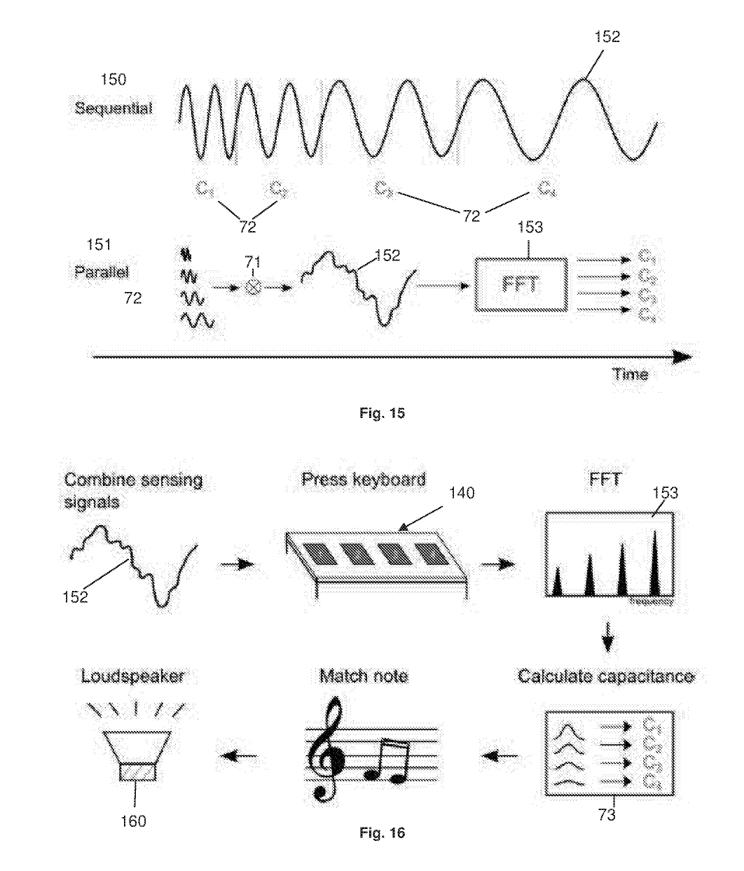

In a preferred example the multiple stimulus signal components 72 can be combined into a single sensing signal or combined signal and then applying a Fast Fourier Transform (FFT) 153 to decompose the amplitude (A) and phase (0) of each frequency to calculate its respective capacitance. Although a FFT 153 system is preferred any system for converting between the frequency domain and time domain is acceptable, for example the discrete Fourier transform. Similarly other techniques may be used for non-frequency stimulus components, the techniques being adapted to separate out each component. This method is significantly faster than sweeping through the frequencies and also ensures that the electrical system is presented to all of the sensing frequencies simultaneously. This is because a limitation of an LCR meter's capacitance sweep is that only one sensing signal 152 can be measured at a time. Since determining the key press requires the comparison of multiple frequencies, this can lead to time lapse errors if the sensor changes before the end of the previous waveform. A comparison between the sequential 150 and parallel 151 measurement techniques is shown in FIG. 15. Although a particular waveform is shown in FIG. 15 this is not fixed and may be varied depending on the frequencies of interest, the selectivity or the preciseness required. Possible waveforms include any signal with the desired frequency components, broad frequency signals such as an impulse (Dirac delta function), step function or white noise signals may be used. A further advantage of the FFT method is that it can determine multiple points of deformation by measuring all off the frequencies at exactly or substantially the same time.

In a particular example of the system shown in FIG. 15 four frequencies 72 (1 kHz, 8 kHz, 14 kHZ, 30 kHz) of approximately 25% increments in lumped capacitance were selected to detect pressure at each of the keys 141 of a device 1 as shown in FIG. 14. For example, frequency 1 measured the first ¼ length of the sensor while frequency 2 measured an additional ¼. These frequency signals were summed together (e.g. in a computer program such as LABVIEW, although this could be performed on a microchip, FPGA, logic circuit or similar device). A current driver (e.g. OPA2141) amplified the signal to the sensor and a data acquisition card (e.g. NI USB 6351) measured the return current via a sensing resistor. Back in LABVIEW, a FFT routine resolved the amplitude and phase angle for the selected frequency components and calculated the corresponding lumped capacitance value for each frequency. A matching algorithm of the capacitance measured using the four frequencies was applied to determine which key was pressed and played the corresponding sound via a loudspeaker 160. The system operation flow chart is shown in FIG. 16.

Capacitance is calculated using any suitable method (such as those disclosed by WO 2010/095960 or WO 2012/053906, for example) and recorded for each of the selected frequencies with no external mechanical or electrical coupling, to provide a reference capacitance. The contents of WO 2010/095960 and WO 2012/053906 are incorporated herein in their entirety by reference.

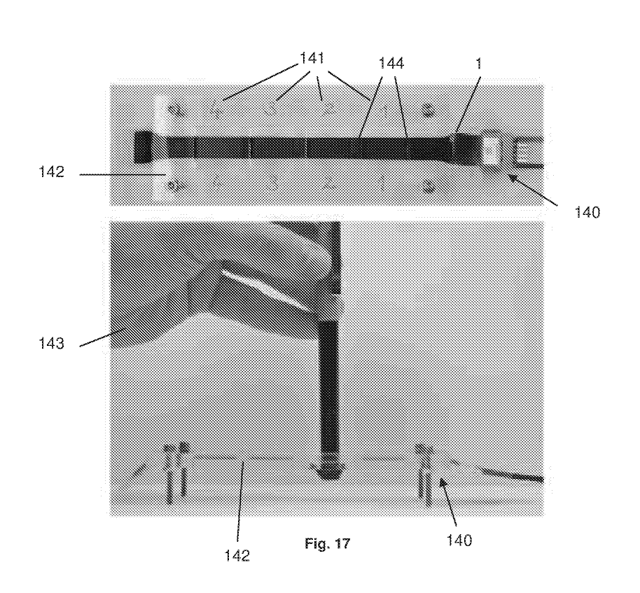

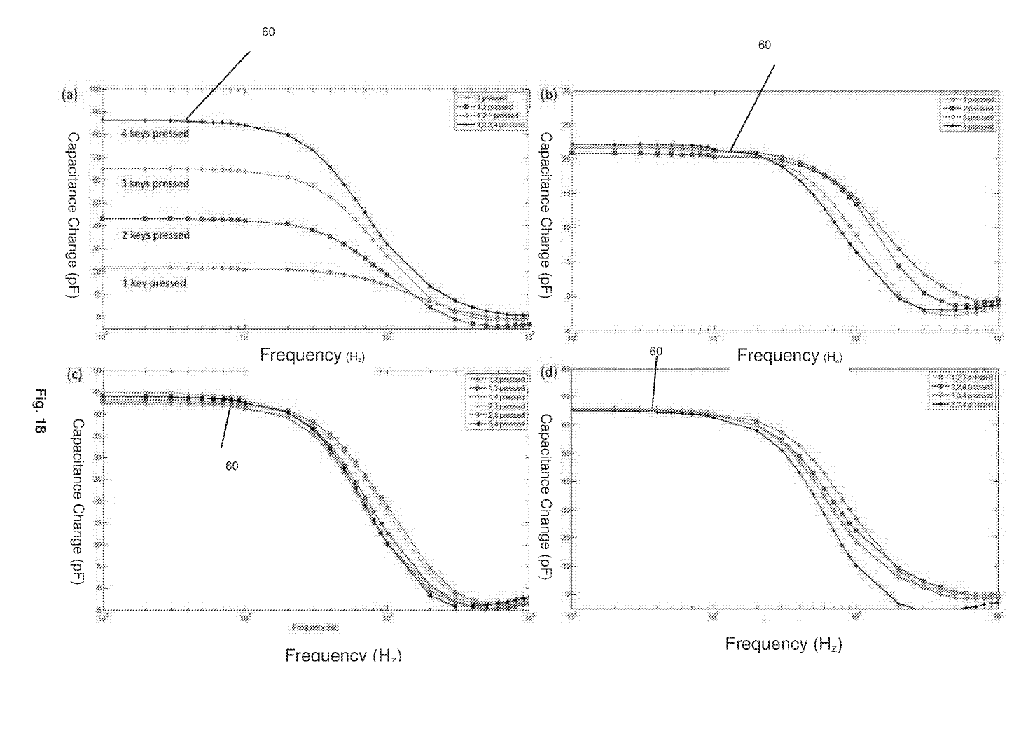

In a particular example a DE 1 keyboard 140 was constructed as shown in FIG. 14. A 100 μm thick silicone dielectric film 10 was sandwiched between 2 compliant electrodes 11a, b containing conductive carbon particles embedded in silicone. The resulting sheet was cut into an approximately area of 0.1 m×0.14 m and metallic terminals were made at one end of each electrode. The nominal capacitance and electrode resistance of the sensor were measured. Four regions 141 (1-4) were marked across the middle to correspond to playing keys. FIG. 17 shows that a frame 142 may be used to isolate strain to particular regions 141. The frame may be made from acrylic with ribs 144 to allow stretch at a particular point to be spatially limited. Alternative frameworks or supports 144 may be used to separate positional areas or keys 141, where the frame or support is used to limit the stretch of particular sections when the next position is pressed. The sensor 140 may be fixed in a plastic frame to isolate strain to the local regions. However alternative systems may not have a frame and may use related capacitance changes in adjacent regions to identify the pressed region.

The capacitance of the dielectric elastomer device may be modified by an external coupling 143 with the device 140, and the position of that change in capacitance can be determined by the apparatus and method of the present invention. The external coupling may comprise a mechanical coupling causing an deformation of the dielectric membrane 1, such as an isolated pressure compressing a region of the dielectric layer, which increases the capacitance between the electrodes in that region. In some embodiments it is important to consider the sensitivity of the sensor to proximity and physical contact. That is the proximity of a hand or implement 143 may affect the capacitance of sensor before physical contact is made. This is due to coupling effect where charge is transferred to the human body capacitance. In some embodiments this increase in the sensor's capacitance may be registered as a physical touch. When physical strain occurs the capacitance will increase further. The effect of proximity of a sensor activator may be variable; for instance a human body's capacitance is variable due to footwear and clothing etc. By shielding the sensor from the sensor activator the proximity effect can be reduced or isolated, limiting or ameliorating any effect on the sensor's reading. FIG. 22 shows an embodiment of shielding 220 where an outer pair of ground electrodes 221, 223 is used to help isolate the sensor electrode 222 from external noise. Increasing the DE's 1 self-capacitance can make it less prone to environmental effects.

Alternatively, or additionally, the external coupling may comprise an electrical coupling of an external capacitance with the device, such as a human finger in close proximity with, or touching, an electrode. The human body can be considered an insulated conductor with the ability to store charge and provide a discharge path, and can be modelled as a 100 pF capacitor in series with a 1.5 kΩ resistor. When a person makes contact with a charged surface such as a dielectric elastomer sensor, they are coupling an external capacitance to the circuit. When a human finger makes contact with the surface of the dielectric elastomer sensor, the human body capacitance is coupled to the system and provides an alternative pathway to ground. This pathway bypasses current from returning to the source, which causes a current drop and voltage rise. Where in this document pressure or position of contact has been discussed it should be understood that this includes both deformation of the sensor by physical contact and proximity or slight contact which couples to the sensor but may not physically deform the sensor. For instance the body may effectively act as an alternative path for current to flow to ground, thereby ‘stealing’ charge away from the sensor. By knowing how the electrode resistance and membrane capacitance is distributed along the sensor and measuring the change in current or voltage, it is possible to predict the location of the contact.

The apparatus and method of the present invention is preferably adapted to sense one of the mechanical or electrical coupling. For example, the electrical coupling may be prevented or minimised by insulating the dielectric elastomer device, or the additional capacitance may be relatively insignificant and ignored or taken into consideration in determining the position of the mechanical coupling. Alternatively, the apparatus may be configured to distinguish between the mechanical and electrical coupling algorithmically or using an additional sensor, such that it can determine the position of both external mechanical and electrical couplings.

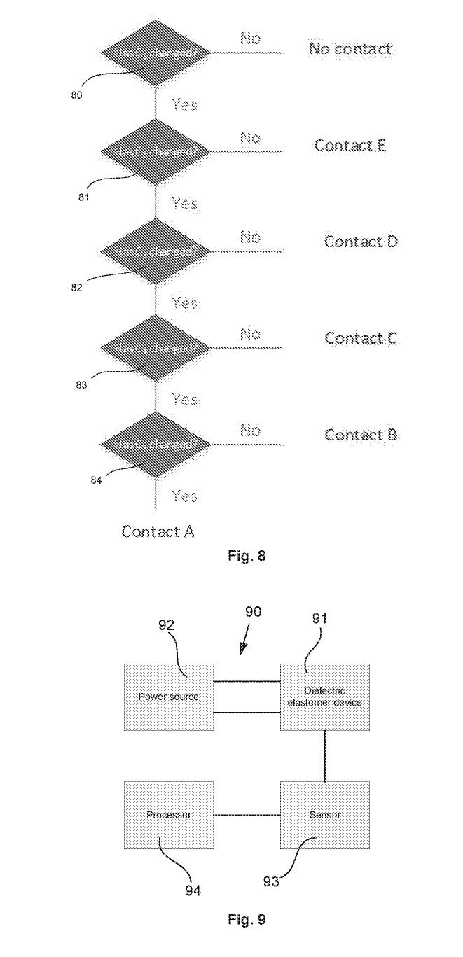

The position of a proximity, touch, and/or pressure applied to the dielectric elastomer device 140 can be determined as shown in the flowchart of FIG. 8, by sequentially comparing changes in the calculated capacitances measured by each of five stimulus frequencies f₁-f₅ (C₁-C₅), with respect to the corresponding reference capacitances. It should be noted that FIG. 8 considers a DED with 5 positions and frequencies instead of the 4 previous considered. Alternatively the difference between a first frequency and a second frequency, associated with a first and second section or location may be used to calculate the capacitance between the locations or sections.

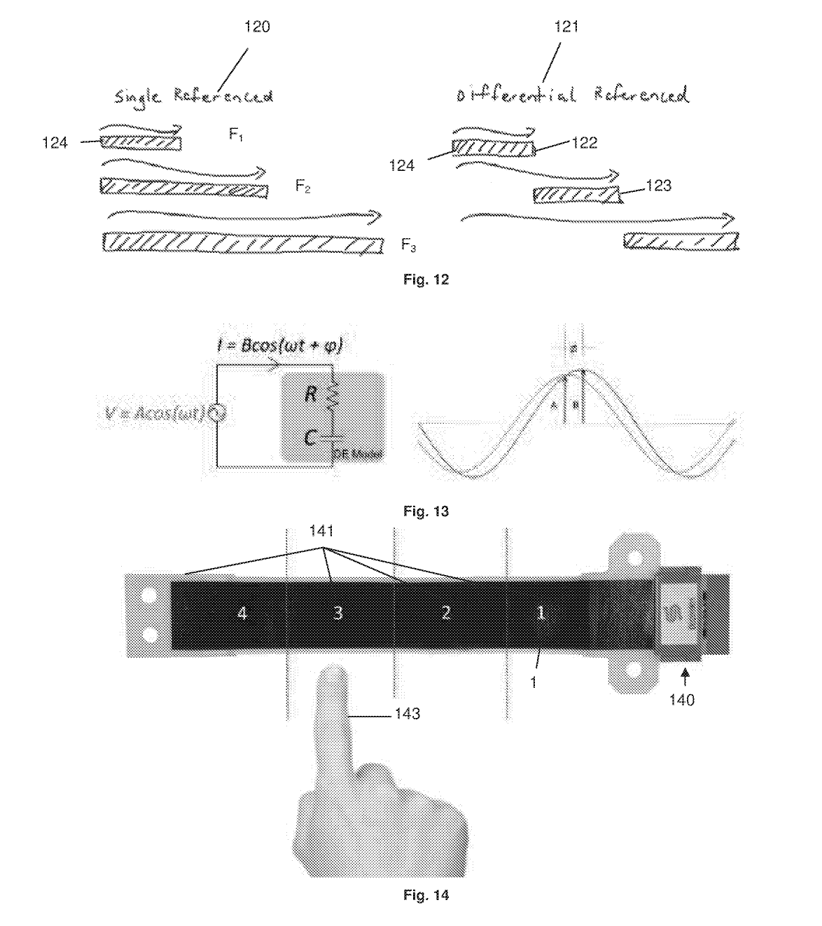

FIG. 12 shows a method of calculating the frequency difference between two sections, labelled as differentially 121 referenced. By using differential reference 121 the noise in the signal may be reduced as the capacitance measured is between the region boundaries 122, 123 instead of including the capacitance from the beginning of the DE 124. That is the noise over the remaining sensor is, at least in part, included in both measurements and therefore cancelled out. In both methods a threshold can be applied to the differential capacitance for each section to determine if a significant change was registered. In a further embodiment the steps shown in the flowchart of FIG. 8 may be applied substantially simultaneously to improve sensing speed. The methods may also be understood as: using the capacitance difference between two frequencies to infer the amount of capacitance in between a section (that is the frequencies measure a certain distance along the sensor and the difference between the capacitances measured corresponds to the capacitance of that section; and using capacitance measured at a single frequency associated with a known position (that is a frequency measures the capacitance to a particular point of contact).

At first step 80, a determination is made as to whether the capacitance calculated from the lowest frequency component f₁ of the stimulus signal varies with respect to the corresponding reference capacitance, which represents the expected capacitance if there is no external coupling with the dielectric elastomer device. To minimise the effect of noise, discretization errors and the like, there may be a margin or threshold about the reference before such a variation is deemed to be determined. If no variation is detected, there is no external coupling anywhere in the device, since the lowest frequency stimulus signal preferably propagates fully through the dielectric elastomer device. The algorithm may therefore stop at this point, or more preferably repeat this step until an external coupling is detected. If a variation is detected, there is an external coupling but the position is not yet known.

At a second step 81, a determination is made as to whether to capacitance calculated from the second lowest frequency f₂ varies with respect to the corresponding reference capacitance. Since this frequency is attenuated by the dielectric elastomer device roughly between the regions D and E, the calculated capacitance represents a portion of the area dielectric elastomer actuator corresponding with the regions A-D. No variation or change from the reference capacitance indicates that the external coupling must have occurred in region E. The algorithm may therefore stop at this point, repeat from the beginning, or continue to confirm there are no anomalies. If a variation is detected, the external coupling is somewhere within regions A-D, and the position may be further refined by continuing to third step 82.

In steps 82 and 83, the same determination is in turn repeated for frequencies f₃ and f₄, respectively.

At the final step 84, if no change is detected in capacitance C₅, corresponding with the stimulus component at the highest frequency f₅, the external coupling is determined to be in region B. If there is a variation, the external coupling is determined to be in region A.

The magnitude of pressure exerted, and degree of external coupling, can be determined from the degree of variation of the calculated capacitance from the respective reference capacitance. In one embodiment this may be enabled by recording the time history of the detection of the external coupling, e.g. the capacitance. For instance, an initial increase, followed by another increase might signal irstly the coupling then the added mechanical deformation.

From the foregoing process it will be appreciated that the resolution of the position information is dependent on both the size of the dielectric elastomer device and the number of different frequencies analysed. Any number of frequencies may be used dependent on the specific requirements, without departing from the scope of the invention.

The described process is merely an example of an algorithm which may be used to determine the position of an external coupling according to the present invention. In an alternative embodiment according to a further example, all of the capacitances for frequencies f₁-f₅ may be calculated and compared with the corresponding reference capacitances, and the position of the external coupling (if any) determined based merely upon the number of calculated capacitances varying from their respective reference value.

FIG. 18 shows the capacitance frequency response of single and multiple touch positions on a device as shown in FIG. 14. To sense multiple regions within the same sensor, four sensing frequencies were mixed together and applied to the DE. The FFT algorithm was used to distil the amplitude and phase of each frequency component simultaneously and calculate its corresponding capacitance. The curves show that different key presses provide unique characteristic profiles or curves; in this example the curves are capacitance frequency response. That is a characteristic curve is produced for a plurality of pressures on the sensor. Pressing two different locations on the sensor affected the frequency response differently. That is, sensing simultaneous multiple deformations on the dielectric elastomer, such as in the case of multi-touch sensors, a unique capacitance frequency response profile can be used to identify which regions were deformed. By collecting multiple frequency data points and matching these against a predetermined calibration curve, the combination of regions were deformed can be identified. This information may be fed into a look-up table to allow detection of the position of an external coupling. In an embodiment an approximation of the electrical properties R′ (e.g. by a 4-point probe test) and C′ (by approximation of the thickness of the dielectric layer) may be obtained without, or with limited measurements. As both of these measurements are recorded in respective units per length these can be extrapolated to the length of the device or dielectric 1.

Looking first at FIG. 18a, which shows the effect of multiple keys being pressed at the same, the lowest frequency signal (e.g. 100 Hz) (left hand side (LHS) of the figures), was affected by all four press locations while the higher frequencies (attenuated by the impedance of the DE) on the RHS (right hand side) were less sensitive the further away. Therefore, the low frequencies can provide a good indication on the total number of keys pressed. FIG. 18b shows the effect of pressing the different keys or positions on the sensor. Here a higher frequency, e.g. 10 KHZ shows a larger difference between the positions: pressing the sensor at position 1 causes approximately 15 pF change in capacitance compared to only 5 pF when position 4 was pressed. FIG. 18c shows the differences observable at higher frequencies when two location combinations are pressed and FIG. 18d shows the differences when 3 key combinations are pressed. In an embodiment the low frequencies could be used to determine the number of positions sensed and the high frequencies to then narrow down the appropriate curve. In a further embodiment the frequency curve may be reviewed as a whole to provide the best match to the predetermined curves.

In effect the characteristic footprint is similar to a digital barcode where each frequency reveals some further information about where on the sensor was pressed. Therefore the use of a plurality of frequencies may provide further information about the key presses, for instance by combining a high and low frequency or some set, range or combination of frequencies. Alternatively the frequency measurements may be used to generate a curve 60 and a, or a plurality of, characteristic of the curve may be used to distinguish the pressures. For example using a mapping technique, the position/s on the DE sensor that was pressed can be determined and the corresponding sound played via the loudspeaker. The mapping technique may correlate the measured results with pre-calibrated values. Some form of statistical or regression analysis such as least squares regression may be used to improve the mapping technique. Although a keyboard 140 has been described the key presses or location has wide potential uses and may be fed into a microprocessor or similar.

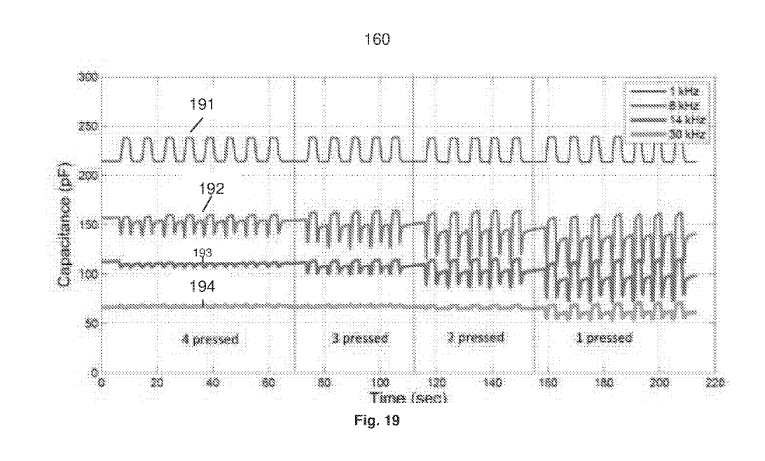

FIG. 19 shows a plot of the changing capacitance with time when a series of keys 141 are pressed and measured at four different frequencies. In this example position 4 is the furthest from the sensor measurement position. When position 4 is pressed a change of capacitance occurs at the lowest frequency 191 and a smaller change at the second lowest frequency 192. In comparison when location 1 is pressed all of the frequencies react, including the third 193 and fourth highest frequencies 194. This is in agreement with the curves shown in FIG. 18b as the plots at 30 KHZ show little change when either 3 or 4 are pressed and a much large change when 1 or 2 are pressed. This is also in agreement as each press has a similar effect at the lowest frequency. The oscillatory nature of the signal represents the periodic pressing of the switches. Using faster hardware and/or software may enable the time between measurements to be reduced.

A system diagram diagrammatically illustrating the components of a sensor apparatus 90 according to the present invention is shown in FIG. 9. Broadly speaking, the apparatus comprises the dielectric elastomer device 91, a power source 92 coupled with the electrodes of the dielectric elastomer device to apply a stimulus signal between the electrodes, a sensor 93 coupled with the electrodes to obtain a sensing signal indicative of a frequency response of the dielectric elastomer device; and a processor 94 coupled with the sensor to receive and process the sensing signal. In at least some embodiments, the processor may also be coupled with the power source to control application of the stimulus signal.

The dielectric elastomer device 1 preferably comprises a volumetrically-incompressible soft dielectric membrane 10 sandwiched between resistive electrodes 11a, 11b. The electrodes are considered non-ideal in that the resistance of the imperfect conductors is generally undesirable for most applications, but this non-ideal property is exploited by the present invention as described above.

The term “processor” 94 is used in the broad sense to encompass any and all software and/or hardware components which process the sensing signal to determine a condition, degree, and/or position of external coupling. It may comprise hardware-based filters and a series of voltage comparators to perform the method of the flowchart of FIG. 8, for example, entirely removing the need for programmable hardware and software filters, for example. Alternatively, the processor 94 would generally be implemented at least in part in software using embedded reconfigurable or programmable hardware components such as a programmable logic device (PLD) or field programmable gate arrays (FPGA), or more preferably a digital processor which may comprise a digital signal processor (DSP) and/or microcontroller executing embedded software programmed to implement the system and perform the methods of the invention described herein. Most commonly, however, it is expected that the processor 94 would be implemented as an embedded system using a combination of software and discrete hardware components.

Once they are programmed to perform particular functions pursuant to instructions from program software that implements the method of this invention, such digital logic and/or digital processor devices in effect become special-purpose computers particular to the method of this invention. The techniques necessary for this are well-known to those skilled in the field of embedded systems.

Although this invention has been described by way of example and with reference to possible embodiments thereof, it is to be understood that modifications or improvements may be made thereto without departing from the scope of the invention. For example, it may be possible to form a two- or three-dimensional sensor apparatus using multiple stimulus signals 204 and triangulation techniques, for example. Alternatively, or additionally, the dielectric elastomer device might be used simultaneously as both a sensor and actuator, to provide haptic feedback for example.

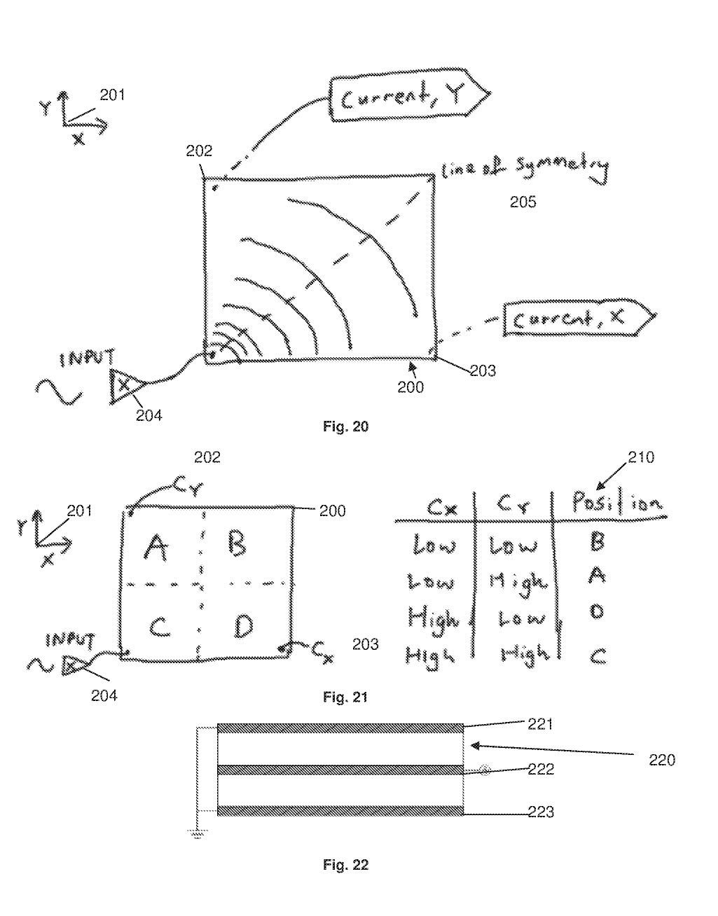

FIG. 20 shows a 2 dimensional sensing system occurring where the dielectric elastomer width is not small in comparison to its length. In the case of 2 dimensions such as a dielectric elastomer sensor sheet 200, the X-Y position 201 of deformation can be inferred by adding a second return electrode 202, 203 to compare the respective capacitances. In an embodiment the return electrodes 202, 203 are positioned at first and second separated positions to measure the sensing signal, e.g. current (Current, Y and Current, X). Preferably these positions are at opposite corners of the sheet 200, but other positions are possible. By calculating the capacitance at these points, we can determine the 2-dimensional position of where deformation occurred. For instance, along the line of symmetry 205, any deformation will cause the same change in capacitance at outputs X and Y 202, 203. The magnitude of this capacitance change provides a measure of the radial distance from the origin to which the deformation occurred. A look up table 210 similar to that shown in FIG. 21 shows how the relative change between X and Y can then be used to determine if the deformation occurred on the left or right side of the line of symmetry 205. In an embodiment this could be extended to a 3D system by combining a series of two dimensional systems in parallel (e.g. forming the sides of a cube, or by having a third sensor mounted along the third axis.

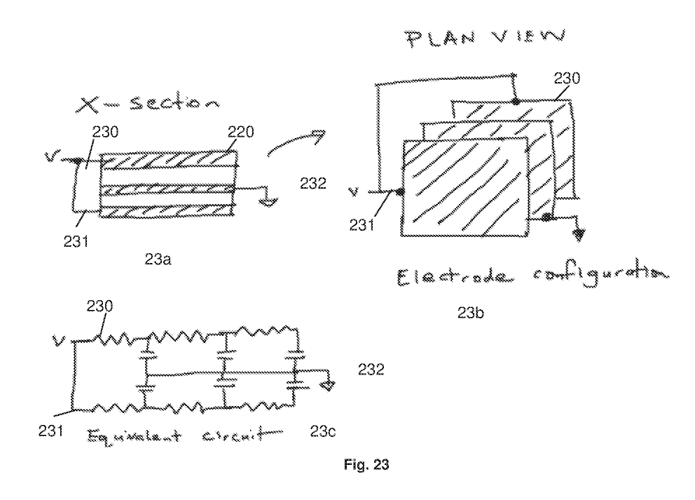

FIG. 23 shows an alternative embodiment of a 2-dimensional sensing dielectric device 220 where multiple layers of 1-dimensional sensors are stacked. That is there are three electrodes 221, 222, 223. FIG. 23a shows an alternative arrangement of two independent sensors laminated back to back. Each sensor has a sensing signal input 230, 231 (and return electrode or output) and these are arranged at substantially orthogonally or at 90 degrees to each other as shown in FIG. 23b. Detecting the position along each of these directions would thereby determine the position along each axis. In other embodiments alternative axes may be used that better reflect the switch geometry. The independent sensors may be bonded mechanically (to couple strain) and configured at approximately 90 degrees to each other. Each sensor effectively measures the position along one dimension. This can be achieved using a 5 layer sensor consisting of 3 layers of electrodes and two layers of dielectric in between. FIG. 23c shows the sensing signal applied to the outside 2 electrodes 230, 231 with the middle electrode as the common ground 232. The described transmission line theory in 1D is applied to each layer. This system also may provide a 3D sensing system by building a stack of electrodes, e.g. having 10 or 20 layers or more. Alternatively further layers could be included for shielding purposes.

The user inputs received and processed by the present invention may be used for purposes as simple as turning on or off or adjusting the brightness of a light emitting diode (LED), or more complex applications such as controlling the position of a cursor upon a computer display, for example. The 2D system can provide applications such as Touch pads, keyboard, telephone buttons and other input systems. As the dielectric elastomers can be manufactured as bendable or flexible sensors the external coupling can be determined around an uneven surface including curved or conical surfaces. In a particular embodiment the 2D sheet could be wrapped around an object or body to determine movement. In an example the sensor could be wrapped about a portion of a human or animal body, such as a human knee joint. The sensor would then be able to sense movement of the human knee joint and where the movement was taking place.

The embodiments of the invention described above utilise a substantially planar dielectric elastomer device in which the electrodes and dielectric membrane each have a substantially uniform thickness across their full area. However, many variations of the device are possible without departing from the spirit or scope of the invention. For example, the resistive and/or capacitive properties can be changed by:
1. Changing the capacitance by varying the geometry. This can be achieved by a gradually varying thickness of the dielectric layer, or changing the overlapping area of the electrodes to reduce the active area of the dielectric elastomer device, respectively. This changes the local capacitance profile of the sensor. Changing the thickness (or other geometry of the sensor) might be able to amplify the detected change from a given stretch and could be useful to increase sensitivity;
2. Changing the capacitance by changing the dielectric constant within the device. This can be through the use of different dielectric materials;
3. Changing the electrode resistance by changing the geometry of the device. This can be a change or variation in the cross sectional area or length of the electrodes;
4. Changing the electrode resistance gradient along the sensor. This can be achieved by using different concentrations of the same material as shown in FIG. 13, or different materials for the electrode; and/or
5. Adding external impedances in series or parallel to change the input impedance of the sensor. For instance, putting a conductive mesh on top of the sensor reduces its effective electrode resistance.

In an alternative embodiment which allows for further abstraction and speed improvement, the FFT procedure can implemented in hardware using an FPGA achieving a similar function to dedicated gain and phase detectors ICs such as the AD8302. A further advantage of doing the FFT is that it is inherently a band-pass filter where only the targeted signal frequencies are taken calculated. This avoids spectral noise creeping into the signals of interest.

In a further embodiment the tactile sensing application may be improved by eliminating electrical noise such as any stray capacitances. The human body capacitance (HBC) is equivalent to a 100 pF capacitor and can be as large as 400 pF depending on footwear and floor insulations. Directly coupling a relatively large capacitance (e.g. a person's finger) can significantly affect the efficacy of the capacitance mapping process. The large capacitance can increase the DE's self-capacitance and sensitivity to make it less prone to environmental disturbances. In an embodiment shielding, for example in the form of a pair of outer ground electrodes, can help isolate the sensor from environmental noise as shown in FIG. 22.

The invention may also be said broadly to consist in the parts, elements and features referred to or indicated in the specification of the application, individually or collectively, in any or all combinations of two or more of said parts, elements or features. Furthermore, where reference has been made to specific components or integers of the invention having known equivalents, then such equivalents are herein incorporated as if individually set forth.

From the foregoing it will be seen that a touch sensing dielectric elastomer device and method are provided which enable the use of dielectric elastomer devices for human-computer interaction and/or control of other electronic devices. The dielectric elastomer touch sensor offers several advantages, in particular that it is lightweight, soft (i.e. flexible or pliable), and/or stretchable.

Unless the context clearly requires otherwise, throughout the description, the words “comprise”, “comprising”, and the like, are to be construed in an inclusive sense as opposed to an exclusive or exhaustive sense, that is to say, in the sense of “including, but not limited to”.

Any discussion of the prior art throughout the specification should in no way be considered as an admission that such prior art is widely known or forms part of common general knowledge in the field.

1. A sensor apparatus comprising:
a dielectric elastomer device;
a source coupled with the dielectric elastomer device to apply a stimulus signal to the dielectric elastomer device, the stimulus signal comprising a plurality of stimulus components of different characteristics;
a sensor coupled with the dielectric elastomer device to obtain a sensing signal indicative of a response of the dielectric elastomer device; and
a processor coupled with the sensor to receive the sensing signal, and configured to detect an external coupling with the dielectric elastomer device based on the variation in the response of the dielectric elastomer device to the plurality of stimulus components.

2. The sensor apparatus of claim 1 wherein the stimulus signal supplies the two or more stimulus components concurrently.

3. The sensor apparatus of claim 1 wherein the external coupling comprises at least one of:
a mechanical coupling causing deformation of the dielectric elastomer device; and/or
an electrical coupling of an external capacitance with the dielectric elastomer device.

4. The sensor apparatus of claim 1 wherein at least one of the two or more stimulus components is at least partially attenuated by the dielectric elastomer device.

5. The sensor apparatus of claim 1 wherein the processor is configured to process the sensing signal to identify two or more sensing components of the sensing signal, each attributable to one of the two or more different stimulus components of the stimulus signal.

6. The sensor apparatus of claim 1 wherein the processor is configured to perform a transform on the sensing signal to identify two or more sensing components corresponding to the two or more stimulus components.

7. The sensor apparatus of claim 6 wherein the processor is configured to calculate, for each of the two or more sensing components, a capacitance of the dielectric elastomer device based at least in part on the respective sensing signal.

8. The sensor apparatus of claim 7 wherein the processor is further configured to compare the calculated capacitances with corresponding reference capacitances or the difference between calculated capacitances, for each of the different sensing components, wherein a variation between the calculated capacitance and reference capacitances is indicative of the external coupling.

9. The sensor apparatus of any one of claim 8 wherein each of the calculated capacitances corresponds with a portion of the dielectric elastomer device, each of the portions extending distally over an area having an inverse relationship to a frequency of the respective stimulus and/or sensing component.

10. The sensor apparatus of claim 8, wherein the processor is configured to detect the position of the external coupling based at least in part upon which of the calculated capacitances vary from their respective reference capacitances or a curve constructed from the respective reference capacitances.

11. The sensor apparatus of claim 8, wherein the processor is configured to sequentially compare the respective calculated capacitances and reference capacitances in ascending order of a frequency of the corresponding stimulus/sensing components, wherein:
an output signal indicating no external coupling of the dielectric elastomer device is provided if the first calculated capacitance does not vary;
an output signal indicating of the external coupling with the dielectric elastomer device is provided if the first calculated capacitance varies; and/or
an output signal indicating a position of the external coupling with the dielectric elastomer device is provided if at least one of the calculated capacitances varies, wherein the position is determined by identifying a first occurrence of a calculated capacitance in the sequence which does not vary.

12. The sensor apparatus of claim 8, wherein the comparison between calculated and reference capacitances, or the difference between calculated capacitances, comprises a minimum margin of difference for indicating an external coupling

13. The sensor apparatus of claim 1 comprising a one-dimensional sensor, wherein the dielectric elastomer device has a substantially elongate planar shape.

14. A method for determining a position of an external coupling with a dielectric elastomer device, the method comprising steps of:
applying a stimulus signal to the dielectric elastomer device, the stimulus comprising a plurality of stimulus components each stimulus component having a different characteristic;
measuring a response of the dielectric elastomer device to each of the plurality of stimulus components;
determining an external coupling based at least in part on the variation in the response of the dielectric elastomer device to the plurality of stimulus components.

15. The method of claim 14 comprising performing a transform on the response to separate at least some of the stimulus components.

16. The method of claim 14 further comprising calculating a capacitance based on the response for each of the stimulus components, and the step of detecting variations in the response comprises detecting variations in the calculated capacitances with respect to corresponding reference capacitances or between calculated capacitances.

17. The method of claim 14 wherein the stimulus signal is an electrical signal having a varying current and/or voltage.

18. The method of claim 14 wherein the characteristic is frequency.

19. The method of claim 14 wherein the stimulus components are applied and/or measured substantially concurrently.

20. The method of claim 14 comprising the step of determining a plurality of external couplings to the dielectric elastomer device and/or their positons.
